(19) United States
(12) Patent Application Publication
(10) Pub. No.: US 2023/0203639 A1
(43) Pub. Date: Jun. 29, 2023

(54) Pt-OXIDE SPUTTERING TARGET AND PERPENDICULAR MAGNETIC RECORDING MEDIUM

(71) Applicant: TANAKA KIKINZOKU KOGYO K.K., Tokyo (JP)

(72) Inventors: Kim Kong Tham, Ibaraki (JP); Tomonari Kamada, Ibaraki (JP); Ryousuke Kushibiki, Ibaraki (JP)

(21) Appl. No.: 17/926,571

(22) PCT Filed: May 17, 2021
(86) PCT No.: PCT/JP2021/018559

§ 371 Date: Nov. 18, 2022

(30) Foreign Application Priority Data
May 18, 2020 (JP) 2020-086785

(51) Int. Cl. C23C 14/08; C23C 14/34; G11B 5/851; G11B 5/66

(52) U.S. Cl. CPC C23C 14/08; C23C 14/3407; G11B 5/851; G11B 5/66

(57) ABSTRACT

Provided is a magnetic recording medium having a large magnetocrystalline anisotropy constant Kᵤ and a high coercivity H_{c} as well as a sputtering target used for producing such a magnetic recording medium.

A Pt-oxide-based sputtering target consists of 60 vol % or more and less than 100 vol % of a Pt-base alloy phase and more than 0 vol % and 40 vol % or less of an oxide, where the Pt-base alloy phase contains 50 at % or more and 100 at % or less of Pt.

### TECHNICAL FIELD

The present invention relates to a Pt-oxide-based sputtering target and a perpendicular magnetic recording medium and particularly relates to a perpendicular magnetic recording medium as a microwave-assisted magnetic recording medium and to a Pt-oxide-based sputtering target used for forming such a perpendicular magnetic recording medium by magnetron sputtering.

### BACKGROUND ART

In a magnetic disk of a hard disk drive, information signals are recorded in tiny bits of a magnetic recording medium. To further increase the recording density of the magnetic recording medium, it is necessary to shrink the size of each bit that retains a piece of recorded information while enhancing a signal-to-noise ratio, which is an indicator of information quality. To enhance a signal-to-noise ratio, it is essential to increase a signal or to reduce a noise.

In such a magnetic disk of a hard disk drive, a CoPt-base alloy-oxide granular magnetic thin film has been used as a magnetic recording film that performs recording of information signals (see Non Patent Literature (NPL) 1, for example). The granular structure is formed from columnar CoPt-base alloy grains and the surrounding oxide grain boundaries. To increase the recording density of such a magnetic recording medium, it is necessary to smoothen transition regions between recording bits and thereby to reduce noise. To smoothen transition regions between recording bits, it is essential to reduce the size of CoPt-base alloy grains contained in the magnetic thin film. For this reason, to further increase the recording density in such a CoPt-base alloy-oxide granular magnetic thin film to be formed at room temperature, it is necessary to reduce the size of CoPt-base alloy grains contained in the magnetic recording layer (magnetic thin film).

Meanwhile, as a result of further reduction in the size of CoPt-base alloy grains, there arise so-called thermal fluctuations, in which recorded signals are lost due to the thermal stability impaired by superparamagnetism. Such thermal fluctuations are a major obstacle to a higher recording density of a magnetic disk.

To overcome this obstacle, it is necessary to increase the magnetic energy in each CoPt-base alloy grain so as to predominate over the thermal energy. The magnetic energy of each CoPt-base alloy grain is determined by v×Kᵤ, which is the product of the volume v and the magnetocrystalline anisotropy constant Kᵤ of the CoPt-base alloy grain.

Accordingly, to increase the magnetic energy of the CoPt-base alloy grain, it is essential to increase the magnetocrystalline anisotropy constant Kᵤ of the CoPt-base alloy grain (see NPL 2, for example).

To grow columnar CoPt-base alloy grains having a large Kᵤ, it is essential to realize the phase separation between each CoPt-base alloy grain and a grain boundary material. When the interactions between CoPt-base alloy grains increase due to unsatisfactory phase separation between each CoPt-base alloy grain and a grain boundary material, the coercivity H_{c} of a CoPt-base alloy-oxide granular magnetic thin film decreases. Consequently, thermal fluctuations tend to arise due to impaired thermal stability. Accordingly, it is also important to reduce interactions between CoPt-base alloy grains.

Exemplary measures for increasing the Kᵤ of CoPt-base alloy grains include adjusting Co and Pt contents in each CoPt-base alloy grain and thereby increasing the spin-orbit interaction, reducing stacking faults, and improving the periodicity in the stacking structure of Co atoms and Pt atoms through film deposition in a high-temperature substrate heating process (see NPL 3 and 4, for example). However, since the composition of the existing CoPt-base alloy-oxide magnetic thin films has already been optimized satisfactorily, further adjustment is impossible. Moreover, it has been known that Kᵤ deteriorates when the currently used CoPt-base alloy-oxide granular magnetic thin films are prepared by a high-temperature substrate heating process (NPL 5, for example). Further, it has been known that multilayers of Co and Pt thin films formed at room temperature exhibit interface magnetic anisotropy in the perpendicular direction (NPL 6, for example).

### CITATION LIST

### Non Patent Literature

NPL 1: T. Oikawa et al., IEEE Transactions on Magnetics, 38, 1976 (2002)
NPL 2: S. N. Piramanayagam, Journal of Applied Physics, 102, 011301 (2007)
NPL 3: A. Ishikawa, R. Sinclair, IEEE Transactions on Magnetics, 32, 3605 (1996)
NPL 4: S. Saito, S. Hinata, M. Takahashi, IEEE Transactions on Magnetics, 50, 3201205 (2014)
NPL 5: K. K. Tham, S. Hinata, S. Saito, M. Takahashi, Journal of Applied Physics, 115, 17B752 (2014)
NPL 6: C. J. Lin, G. L. Gorman, C. H. Lee, R. F. C. Farrow, E. E. Marinero, H. V. Do, H. Notarys, C. J. Chien, Journal of Magnetism and Magnetic Materials, 93, 194 (1991)

### SUMMARY OF INVENTION

### Technical Problem

An object of the present invention is to provide a magnetic recording medium having a large magnetocrystalline anisotropy constant Kᵤ and a high coercivity H_{c} as well as to provide a sputtering target used for producing such a magnetic recording medium.

### Solution to Problem

The present inventors found possible to increase the coercivity H_{c} and the magnetocrystalline anisotropy constant Kᵤ of a magnetic recording medium, not by optimizing the composition of a magnetic thin film that constitutes a magnetic layer, but rather by stacking, on or under a magnetic layer, a thin film layer (buffer layer) having the composition different from that of the magnetic layer, thereby completing the present invention.

According to the present invention, provided is a Pt-oxide-based sputtering target consisting of 60 vol % or more and less than 100 vol % of a Pt-base alloy phase and more than 0 vol % and 40 vol % or less of an oxide, characterized in that the Pt-base alloy phase contains 50 at % or more and 100 at % or less of Pt.

The Pt-base alloy phase preferably further contains, in total, 0 at % or more and 50 at % or less of one or more selected from Si, Ti, Cr, B, V, Nb, Ta, Ru, Mn, Zn, Mo, W, and Ge.

The oxide is preferably one or more selected from B₂O₃, WO₃, Nb₂O₅, SiO₂, Ta₂O₅, TiO₂, Al₂O₃, Y₂O₃, Cr₂O₃, ZrO₂, and HfO₂.

Moreover, according to the present invention, provided is a perpendicular magnetic recording medium including: a CoPt-base alloy-oxide granular magnetic layer containing Co-rich grains; and a Pt-base alloy-oxide thin layer (Pt-rich buffer layer) containing Pt-rich grains and being stacked on or under the magnetic layer. The granular magnetic layer consists of 60 vol % or more and less than 100 vol % of a CoPt-base alloy phase and more than 0 vol % and 40 vol % or less of an oxide. The CoPt-base alloy phase of the magnetic layer contains 60 at % or more and 85 at % or less of Co and 15 at % or more and 40 at % or less of Pt. The Pt-base alloy-oxide thin layer (Pt-rich buffer layer) consists of 60 vol % or more and less than 100 vol % of a Pt-base alloy phase and more than 0 vol % and 40 vol % or less of an oxide. The Pt-base alloy phase of the Pt-base alloy-oxide thin layer (Pt-rich buffer layer) contains more than 50 at % and 100 at % or less of Pt.

In a first embodiment of the perpendicular magnetic recording medium of the present invention, the Pt-base alloy-oxide thin layer (Pt-rich buffer layer) is stacked under the CoPt-base alloy-oxide granular magnetic layer, and the Pt-base alloy-oxide thin layer (Pt-rich buffer layer) has a thickness of more than 0 nm and 2 nm or less.

In a second embodiment of the perpendicular magnetic recording medium of the present invention, the Pt-base alloy-oxide thin layer (Pt-rich buffer layer) is stacked on the CoPt-base alloy-oxide granular magnetic layer, and the Pt-base alloy-oxide thin layer (Pt-rich buffer layer) has a thickness of more than 0 nm and 4 nm or less.

A third embodiment of the perpendicular magnetic recording medium of the present invention includes a plurality of combinations, each of which comprises: a CoPt-base alloy-oxide granular magnetic layer; and a Pt-base alloy-oxide thin layer (Pt-rich buffer layer) stacked on the magnetic layer, and the total thickness of the Pt-base alloy-oxide thin layers (Pt-rich buffer layers) included in the perpendicular magnetic recording medium is more than 0 nm and 4 nm or less.

The Pt-base alloy phase of the Pt-base alloy-oxide thin layer (Pt-rich buffer layer) preferably further contains, in total, 0 at % or more and 50 at % or less of one or more selected from Si, Ti, Cr, B, V, Nb, Ta, Ru, Mn, Zn, Mo, W, and Ge.

The Pt-base alloy-oxide thin layer (Pt-rich buffer layer) preferably contains, in total, 0 vol % or more and 40 vol % or less of one or more oxides selected from B₂O₃, WO₃, Nb₂O₅, SiO₂, Ta₂O₅, TiO₂, Al₂O₃, Y₂O₃, Cr₂O₃, ZrO₂, and HfO₂.

### Advantageous Effects of Invention

By including a Pt-base alloy-oxide thin layer (Pt-rich buffer layer) stacked on or under a CoPt-base alloy-oxide granular magnetic layer, the perpendicular magnetic recording medium of the present invention can well separate magnetic grains in the granular magnetic layer compared with conventional perpendicular magnetic recording media. Consequently, interface magnetic anisotropy is exhibited in the perpendicular direction to increase the magnetocrystalline anisotropy constant Kᵤ of the entire magnetic thin film, thereby increasing the coercivity H_{c} as well along with increasing Kᵤ.

### BRIEF DESCRIPTION OF DRAWINGS

FIG. 1 is a schematic vertical sectional view illustrating the stacked state of a Ru underlayer, a Pt-rich thin layer (Pt-rich buffer layer), and a Co-rich magnetic layer of a magnetic recording medium of the present invention.

FIG. 2 is a schematic vertical sectional view illustrating the stacked state of a Ru underlayer and a CoPt magnetic layer of a conventional magnetic recording medium.

FIG. 3-A schematically illustrates the stacking structure of a magnetic recording medium sample A prepared in Examples 1 to 108.

FIG. 3-B schematically illustrates the stacking structure of a magnetic recording medium sample B prepared in Examples 109 to 119.

FIG. 3-C schematically illustrates the stacking structure of a magnetic recording medium sample C prepared in Examples 120 to 122 and Comparative Example 16.

FIG. 4 is a graph showing the relationships between the magnetocrystalline anisotropy constant K_{u grain} solely for magnetic grains of a magnetic recording medium sample and the thickness of the Pt-rich thin layer (Pt-rich buffer layer) measured in Examples 1 to 108.

FIG. 5 is a graph showing the relationships between the coercivity of a magnetic recording medium sample and the thickness of the Pt-rich thin layer (Pt-rich buffer layer) measured in Examples 1 to 108.

FIG. 6 is a graph showing the relationship between the magnetocrystalline anisotropy constant K_{u grain} solely for magnetic grains of a magnetic recording medium sample and the oxide content in the Pt-rich thin layer (Pt-rich buffer layer) measured in Examples 1 to 108.

FIG. 7 is a graph showing the relationship between the magnetocrystalline anisotropy constant K_{u grain} solely for magnetic grains of a magnetic recording medium sample and the thickness of the Co-rich magnetic layer measured in Examples 1 to 108.

FIG. 8 is a graph showing the relationship between the coercivity H_{c} of a magnetic recording medium sample and the thickness of the Co-rich magnetic layer measured in Examples 1 to 108.

FIG. 9 is a graph showing the relationship between the magnetocrystalline anisotropy constant K_{u grain} solely for magnetic grains of a magnetic recording medium sample and the Co content in the Co-rich magnetic layer measured in Examples 1 to 108.

FIG. 10 is a graph showing the relationship between the coercivity H_{c} of a magnetic recording medium sample and the Co content in the Co-rich magnetic layer measured in Examples 1 to 108.

FIG. 11 is a graph showing the relationship between the magnetocrystalline anisotropy constant K_{u grain} solely for magnetic grains of a magnetic recording medium sample and the thickness of the Pt-rich buffer layer (BL thickness) measured in Examples 120 to 122 and Comparative Examples 15 and 16.

FIG. 12 is a graph showing the relationship between the coercivity H_{c} of a magnetic recording medium sample and the thickness of the Pt-rich buffer layer (BL thickness) measured in Examples 120 to 122 and Comparative Examples 15 and 16.

FIG. 13 is a graph showing the relationship between the magnetocrystalline anisotropy constant K_{u grain} solely for magnetic grains of a magnetic recording medium sample and the total thickness of the Pt-rich buffer layers (total BL thickness) measured in Examples 111, 121, and 123 to 130 and Comparative Examples 15 and 17.

FIG. 14 is a graph showing the relationship between the coercivity H_{c} of a magnetic recording medium sample and the total thickness of the Pt-rich buffer layers (total BL thickness) measured in Examples 111, 121, and 123 to 130 and Comparative Examples 15 and 17.

### DESCRIPTION OF EMBODIMENTS

The present invention provides a Pt-oxide-based sputtering target consisting of 60 vol % or more of a Pt-base alloy phase and 40 vol % or less of an oxide. The Pt-oxide-based sputtering target preferably consists of 65 vol % or more (excluding 100 vol %) of a Pt-base alloy phase and 35 vol % or less (excluding 0 vol %) of an oxide and more preferably consists of 70 vol % or more and 90 vol % or less of a Pt-base alloy phase and 10 vol % or more and 30 vol % or less of an oxide.

The Pt-oxide-based sputtering target of the present invention is characterized in that the Pt-base alloy phase contains 50 at % or more (including 100 at %) of Pt. The Pt-base alloy phase preferably contains 60 at % or more and 100 at % or less of Pt and more preferably contains 70 at % or more and 100 at % or less of Pt.

The Pt-base alloy phase may further contain, in total, 50 at % or less (including 0 at %), preferably 0 at % or more and 40 at % or less, and more preferably 0 at % or more and 30 at % or less of one or more selected from Si, Ti, Cr, B, V, Nb, Ta, Ru, Mn, Zn, Mo, W, and Ge.

Examples of the preferable composition (at %) of the Pt-base alloy phase include the following.

(Pt)

(Pt95Si5)

(Pt95Ti5)

(Pt95 Cr5)

(Pt95B5)

(Pt95V5)

(Pt95Nb5)

(Pt95Ta5)

(Pt95Ru5)

(Pt95Mn5)

(Pt95Zn5)

(Pt95Mo5)

(Pt95W5)

(Pt95Ge5)

(Pt95Ti5)

(Pt80Ti10)

(Pt80Ti20)

(Pt70Ti30)

(Pt60Ti40)

(Pt50Ti50)

Preferable exemplary oxides of the Pt-oxide-based sputtering target of the present invention may be one or more selected from B₂O₃, WO₃, Nb₂O₅, SiO₂, Ta₂O₅, TiO₂, Al₂O₃, Y₂O₃, Cr₂O₃, ZrO₂, and HfO₂. The oxide content may be set to, in total, 40 vol % or less (excluding 0 vol %), preferably 10 vol % or more and 40 vol % or less, more preferably 20 vol % or more and 40 vol % or less, and particularly preferably 25 vol % or more and 35 vol % or less.

The Pt-oxide-based sputtering target of the present invention preferably has a microstructure in which the Pt-base alloy phase and the oxide are finely dispersed. By finely dispersing the oxide, it is possible to reduce particles to be generated during sputtering.

The Pt-oxide-based sputtering target of the present invention can be produced by mixing Pt metal powder or Pt-base alloy atomized powder with oxide powder using a ball mill to prepare a mixed powder for sintering, followed by pressure sintering under vacuum at a sintering temperature of 1000° C. or higher and 1300° C. or lower.

The Pt-oxide-based sputtering target of the present invention can suitably be used for producing a perpendicular magnetic recording medium. For example, a novel perpendicular magnetic recording medium of the present invention can be produced by (1) stacking, using the Pt-oxide-based sputtering target of the present invention, a Pt-base alloy-oxide thin layer (Pt-rich buffer layer) on a Ru underlayer and further stacking thereon a granular magnetic layer, (2) stacking, using the Pt-oxide-based sputtering target of the present invention, a Pt-base alloy-oxide thin layer (Pt-rich buffer layer) on a granular magnetic layer stacked on a Ru underlayer, or (3) stacking, using the Pt-oxide-based sputtering target of the present invention, a Pt-base alloy-oxide thin layer (Pt-rich buffer layer) on a granular magnetic layer stacked on a Ru underlayer, then stacking a granular magnetic layer, stacking again, using the Pt-oxide-based sputtering target of the present invention, a Pt-base alloy-oxide thin layer (Pt-rich buffer layer), and repeating these steps.

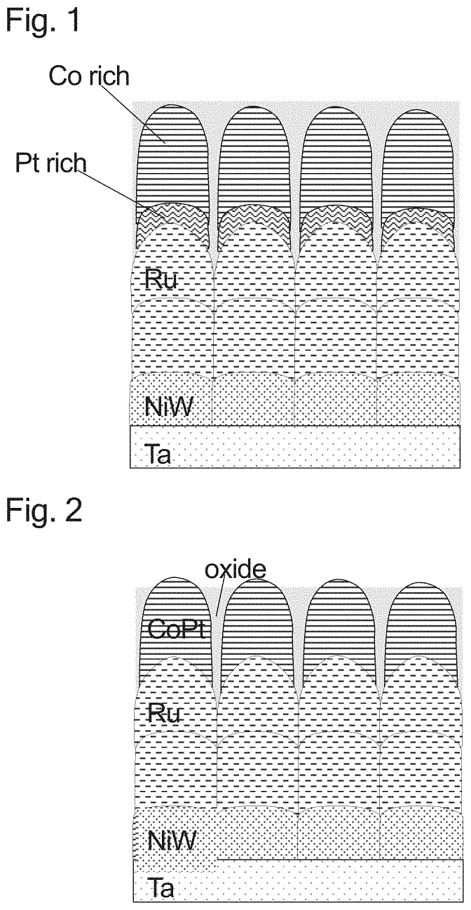

The perpendicular magnetic recording medium of the present invention is characterized by including: a CoPt-base alloy-oxide granular magnetic layer containing Co-rich grains; and a Pt-base alloy-oxide thin layer containing Pt-rich grains and being stacked on or under the magnetic layer. In other words, it is important to stack Pt-rich grains on or under a magnetic layer containing Co-rich grains. As illustrated in FIG. 1, for example, a Pt-base alloy-oxide thin layer containing Pt-rich grains may be disposed between an underlayer containing Ru grains and a magnetic layer containing Co-rich grains. Alternatively, a magnetic layer containing Co-rich grains may be stacked on an underlayer containing Ru grains, and a Pt-base alloy-oxide thin layer containing Pt-rich grains may be stacked on the magnetic layer containing Co-rich grains. Alternatively, a magnetic layer containing Co-rich grains may be stacked on an underlayer containing Ru grains, a Pt-base alloy-oxide thin layer containing Pt-rich grains may be stacked on the magnetic layer containing Co-rich grains, and a magnetic layer containing Co-rich grains may be further stacked thereon. By providing a Pt-base alloy-oxide thin layer containing Pt-rich grains on or under a magnetic layer containing Co-rich grains, an oxide is present between Co-rich magnetic grains of the magnetic layer, between Pt-rich grains, and between Ru grains to form partition walls as illustrated in FIG. 1. Consequently, it is possible to well separate these grains and reduce magnetic interactions between the magnetic grains, thereby increasing the coercivity of the magnetic layer.

The granular magnetic layer of the perpendicular magnetic recording medium of the present invention consists of 60 vol % or more (excluding 100 vol %) of a CoPt-base alloy phase and 40 vol % or less (excluding 0 vol %) of an oxide. The magnetic layer preferably consists of 60 vol % or more and 90 vol % or less of a CoPt-base alloy phase and 10 vol % or more and 40 vol % or less of an oxide and more preferably consists of 70 vol % or more and 80 vol % or less of a CoPt-base alloy phase and 20 vol % or more and 30 vol % or less of an oxide.

The CoPt-base alloy phase of the granular magnetic layer comprises Co-rich grains containing 60 at % or more and 85 at % or less of Co and 15 at % or more and 40 at % or less of Pt. Co is a ferromagnetic metal element and plays a central role in the formation of granular magnetic grains (tiny magnets). Meanwhile, Pt acts to reduce the magnetic moment of the alloy phase and plays a role in adjusting the intensity of magnetism of the magnetic grains.

The CoPt-base alloy phase contains 60 at % or more and 85 at % or less, preferably 65 at % or more and 80 at % or less, and more preferably 70 at % or more and 75 at % or less of Co and 15 at % or more and 40 at % or less, preferably 20 at % or more and 35 at % or less, and more preferably 25 at % or more and 30 at % or less of Pt. The CoPt-base alloy phase may contain elements excluding Co and Pt unless the magnetic characteristics are impaired. Preferable examples of such other elements include Cr, Ru, B, Ti, Si, V, Nb, Ta, Ru Mn, Zn, Mo, W, and Ge. The content of other elements may be set to, in total, 0 at % or more and 20 at % or less, preferably 5 at % or more and 15 at % or less, and more preferably 5 at % or more and 10 at % or less.

Preferable examples of the CoPt-base alloy phase may include the composition (at %) below.

(Co80Pt20)

(Co85Pt15)

(Co70Pt30)

(Co60Pt40)

(Co75Pt20Cr5)

(Co75Pt20B5)

(Co75Pt20Ru5)

(Co75Pt20Ti5)

The oxide of the granular magnetic layer is present between Co-rich grains to form partition walls that separate the Co-rich grains. Preferable examples of the oxide may be at least one selected from B₂O₃, WO₃, Nb₂O₅, SiO₂, Ta₂O₅, TiO₂, Cr₂O₃, Ge₀₂, Al₂O₃, Y₂O₃, ZrO₂, HfO₂, and CoO or combinations thereof. The total oxide content may be set to 40 vol % or less (excluding 0 vol %), preferably 5 vol % or more and 40 vol % or less, and more preferably 10 vol % or more and 35 vol % or less.

The Pt-base alloy-oxide thin layer (Pt-rich buffer layer) stacked on or under the Co-rich magnetic layer consists of 60 vol % or more and less than 100 vol % of a Pt-base alloy phase and more than 0 vol % and 40 vol % or less of an oxide. The Pt-base alloy-oxide thin layer preferably consists of 65 vol % or more (excluding 100 vol %) of a Pt-base alloy phase and 35 vol % or less (excluding 0 vol %) of an oxide and more preferably consists of 70 vol % or more and 90 vol % or less of a Pt-base alloy phase and 10 vol % or more and 30 vol % or less of an oxide.

The Pt-base alloy phase of the Pt-base alloy-oxide thin layer (Pt-rich buffer layer) comprises Pt-rich grains containing 50 at % or more and 100 at % or less of Pt. By including 50 at % or more of Pt, it is possible to increase the magnetocrystalline anisotropy constant Kᵤ. The Pt-base alloy phase preferably contains 60 at % or more and 100 at % or less of Pt and more preferably contains 70 at % or more and 100 at % or less of Pt. The Pt-base alloy phase may contain elements excluding Pt unless the magnetic characteristics of the Co-rich magnetic layer are impaired. Preferable examples of such other elements may be one or more selected from Si, Ti, Cr, B, V, Nb, Ta, Ru, Mn, Zn, Mo, W, and Ge. The content of other elements may be set to, in total, 50 at % or less (including 0 at %), preferably 0 at % or more and 40 at % or less and more preferably 0 at % or more and 30 at % or less.

Examples of the preferable composition (at %) of the Pt-base alloy phase of the Pt-base alloy-oxide thin layer (Pt-rich buffer layer) may include the following.

(Pt)

(Pt95Si5)

(Pt95Ti5)

(Pt95 Cr5)

(Pt95B5)

(Pt95V5)

(Pt95Nb5)

(Pt95Ta5)

(Pt95Ru5)

(Pt95Mn5)

(Pt95Zn5)

(Pt95Mo5)

(Pt95W5)

(Pt95Ge₅)

(Pt95Ti5)

(Pt80Ti10)

(Pt80Ti20)

(Pt70Ti30)

(Pt60Ti40)

(Pt50Ti50)

Preferable examples of the oxide of the Pt-base alloy-oxide thin layer (Pt-rich buffer layer) stacked on or under the Co-rich magnetic layer may be one or more selected from B₂O₃, WO₃, Nb₂O₅, SiO₂, Ta₂O₅, TiO₂, Al₂O₃, Y₂O₃, Cr₂O₃, ZrO₂, and HfO₂. The oxide content may be set to, in total, 40 vol % or less (excluding 0 vol %), preferably 10 vol % or more and 40 vol % or less, more preferably 20 vol % or more and 40 vol % or less, and particularly preferably 25 vol % or more and 35 vol % or less. By setting the oxide content within the above-mentioned range, it is possible to increase the magnetocrystalline anisotropy constant Kᵤ of a magnetic recording medium (see the Examples section described hereinafter).

The Pt-base alloy-oxide thin layer (Pt-rich buffer layer) stacked under the Co-rich magnetic layer has a thickness of more than 0 nm and 2 nm or less. The studies by the present inventors revealed that the thickness of the Pt-rich Pt-base alloy-oxide thin layer (Pt-rich buffer layer) affects the coercivity and the magnetocrystalline anisotropy constant Kᵤ of a magnetic recording medium; the magnetocrystalline anisotropy constant Kᵤ reaches the maximum at the thickness of 0.6 nm; and the coercivity H_{c} reaches the maximum at the thickness of 1.0 nm (see the Examples section described hereinafter). For these reasons, to produce a magnetic recording medium having a large magnetocrystalline anisotropy constant Kᵤ and a high coercivity H_{c}, the thickness of the Pt-rich Pt-base alloy-oxide thin layer (Pt-rich buffer layer) is set to more than 0 nm and 2 nm or less, preferably 0.5 nm or more and 1.5 nm or less, and more preferably 0.8 nm or more and 1.2 nm or less.

The Pt-base alloy-oxide thin layer (Pt-rich buffer layer) stacked on the Co-rich magnetic layer has a thickness of more than 0 nm and 4 nm or less. The studies by the present inventors revealed that the thickness of the Pt-rich Pt-base alloy-oxide thin layer (Pt-rich buffer layer) affects the coercivity H_{c} and the magnetocrystalline anisotropy constant Kᵤ of a magnetic recording medium; the magnetocrystalline anisotropy constant Kᵤ reaches the maximum at the thickness of 0.9 to 1.3 nm; and the coercivity H_{c} reaches the maximum at the thickness of 2.6 nm (see the Examples section described hereinafter). For these reasons, to produce a magnetic recording medium having a large magnetocrystalline anisotropy constant Kᵤ and a high coercivity H_{c}, the thickness of the Pt-rich Pt-base alloy-oxide thin layer (Pt-rich buffer layer) is set to more than 0 nm and 4 nm or less, preferably 0.4 nm or more and 3 nm or less, and more preferably 0.8 nm or more and 2.6 nm or less.

In the case of including a plurality of combinations, each of which comprises a Pt-base alloy-oxide thin layer (Pt-rich buffer layer) stacked on a Co-rich magnetic layer, the total thickness of such Pt-base alloy-oxide thin layers (Pt-rich buffer layers) is more than 0 nm and 4 nm or less. The studies by the present inventors revealed that the total thickness of the Pt-rich Pt-base alloy-oxide thin layers (Pt-rich buffer layers) affects the coercivity H_{c} and the magnetocrystalline anisotropy constant Kᵤ of a magnetic recording medium; the magnetocrystalline anisotropy constant Kᵤ increases at the total thickness of 0.4 to 4 nm; the magnetocrystalline anisotropy constant Kᵤ reaches the maximum at the total thickness of 1.6 nm (=0.4 nm×4 layers); and the coercivity H_{c} reaches the maximum at the total thickness of 0.4 nm (see the Examples section described hereinafter). For these reasons, to produce a magnetic recording medium having a large magnetocrystalline anisotropy constant Kᵤ and a high coercivity H_{c}, the total thickness of the Pt-rich Pt-base alloy-oxide thin layers (Pt-rich buffer layers) is set to more than 0 nm and 4 nm or less, preferably 0.4 nm (=0.2 nm×2 layers) or more and 4 nm (=0.4 nm×10 layers) or less, more preferably 0.8 nm (=0.2 nm×4 layers or 0.4 nm×2 layers) or more and 3.2 nm (=0.32 nm×10 layers or 0.4 nm×8 layers) or less, and particularly preferably 1 nm or more and 3 nm or less. The stacking number is not limited provided that the total thickness of the Pt-rich Pt-base alloy-oxide thin layers (Pt-rich buffer layers) is more than 0 nm and 4 nm or less but is preferably one or more and ten or less and more preferably one or more and eight or less.

The underlayer of the perpendicular magnetic recording medium of the present invention is not particularly limited but is preferably a Ru underlayer of Ru-base alloy phase-oxide. Preferable examples include Ru—SiO₂, Ru—TiO₂, Ru—Ta₂O₅, Ru—B₂O₃, Ru—WO₃, Ru—Nb₂O₅, Ru—MoO₃, Ru—SnO, Ru—Cr₂O₃, RuCo—SiO₂, RuCo—TiO₂, RuCo—Ta₂O₅, RuCo—B₂O₃, RuCo—WO₃, RuCo—Nb₂O₅, RuCo—MoO₃, RuCo—SnO, RuCo—Cr₂O₃, RuCoCr—SiO₂, RuCoCr—TiO₂, RuCoCr—Ta₂O₅, RuCoCr—B₂O₃, RuCoCr—WO₃, RuCoCr—Nb₂O₅, RuCoCr—MoO₃, RuCoCr—SnO, RuCoCr—Cr₂O₃, RuTi—TiO₂, RuTa—Ta₂O₅, RuB—B₂O₃, RuW—WO₃, RuNb—Nb₂O₅, RuMo—MoO₃, RuSn—SnO, and RuCr—Cr₂O₃.

The Pt-rich Pt-base alloy-oxide thin layer (Pt-rich buffer layer) of the perpendicular magnetic recording medium of the present invention can be formed by, for example, (1) after stacking a Ru underlayer, stacking through magnetron sputtering using the Pt-base alloy-oxide sputtering target of the present invention, (2) after stacking a Ru underlayer and a Co-rich magnetic layer, stacking through magnetron sputtering using the Pt-base alloy-oxide sputtering target of the present invention, or (3) after stacking a Ru underlayer and a Co-rich magnetic layer, stacking through magnetron sputtering using the Pt-base alloy-oxide sputtering target of the present invention, further stacking a Co-rich magnetic layer on the resulting Pt-rich buffer layer through magnetron sputtering using a Co-rich sputtering target, then stacking on the resulting Co-rich magnetic layer through magnetron sputtering using the Pt-base alloy-oxide sputtering target of the present invention, and repeating these steps.

### Examples

Hereinafter, the present invention will be described further specifically by means of Examples and Comparative Examples.

[Preparation of Sputtering Targets]

Pt powder or Pt alloy atomized powder (hereinafter, referred to as “Pt-containing powder”) was classified through a sieve to obtain Pt-containing powder of 100 μm or less in particle size. To have the target composition shown in the “composition of Pt-rich layer” in each Example or Comparative Example below, the Pt-containing powder and an oxide powder were mixed in a ball mill to obtain a mixed powder for pressure sintering.

The mixed powder for pressure sintering was hot-pressed under conditions of a sintering temperature of 1000° C. or higher and 1300° C. or lower, a sintering pressure of 25 MPa, a sintering time of 60 minutes, and a sintering atmosphere of vacuum of 5×10⁻² Pa or less to yield a sintered body. The sintered body was processed using a lathe or a surface grinder to prepare a sputtering target of 161.0 mm in diameter×4.0 mm in thickness.

Each raw material powder used for preparing a Pt-containing powder is as follows.

Pt metal powder

PtSi atomized powder

PtTi atomized powder

PtCr atomized powder

PtB atomized powder

PtV atomized powder

PtNb atomized powder

PtTa atomized powder

PtRu atomized powder

PtMn atomized powder

PtZn atomized powder

PtMo atomized powder

PtW atomized powder

PtGe atomized powder

[Preparation of Magnetic Recording Medium Samples A]

Each magnetic recording medium sample A was prepared by stacking on a Ru underlayer, through sputtering with a DC sputtering apparatus using the prepared sputtering target, a Pt-base alloy-oxide thin layer (Pt-rich buffer layer) having the composition shown in each Example or Comparative Example below at the thickness shown in each Example or Comparative Example and then stacking, on the resulting Pt-rich buffer layer, a Co-rich magnetic layer of CoPt-base alloy-oxide having the composition shown in each Example or Comparative Example at the thickness shown in each Example or Comparative Example.

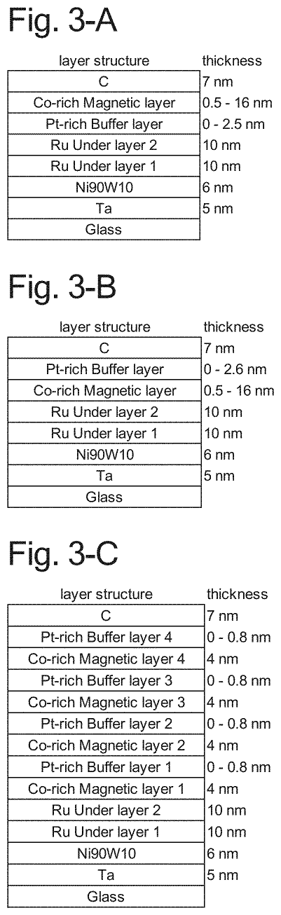

As shown in FIG. 3-A, each magnetic recording medium sample A comprises, on a glass substrate, a Ta layer (5 nm, 0.6 Pa), a Ni90W10 seed layer (6 nm, 0.6 Pa), a Ru underlayer 1 (10 nm, 0.6 Pa), a Ru underlayer 2 (10 nm, 8.0 Pa), a Pt-rich layer (0 to 2.5 nm, 4 Pa), a Co-rich magnetic layer (0.5 to 16 nm, 4 Pa), and a C surface protective layer (7 nm, 0.6 Pa) stacked in this order. Here, the figures within the parentheses represent the thickness (nm) and the Ar atmosphere pressure (Pa) during sputtering. The Ru underlayer 2 is a layer stacked for forming a surface concavo-convex shape. The Pt-rich layer and the Co-rich magnetic layer were deposited at room temperature without elevating the temperature of the substrate.

[Preparation of Magnetic Recording Medium Samples B]

Each magnetic recording medium sample B was prepared, through sputtering with a DC sputtering apparatus using the prepared sputtering target, by stacking, on a Ru underlayer, a Co-rich magnetic layer of CoPt-base alloy-oxide having the composition shown in each Example or Comparative Example below at the thickness shown in each Example or Comparative Example and then stacking, on the resulting Co-rich magnetic layer, a Pt-base alloy-oxide thin layer (Pt-rich buffer layer) having the composition shown in each Example or Comparative Example at the thickness shown in each Example or Comparative Example.

As shown in FIG. 3-B, each magnetic recording medium sample B comprises, on a glass substrate, a Ta layer (5 nm, 0.6 Pa), a Ni90W10 seed layer (6 nm, 0.6 Pa), a Ru underlayer 1 (10 nm, 0.6 Pa), a Ru underlayer 2 (10 nm, 8.0 Pa), a Co-rich magnetic layer (0.5 to 16 nm, 4 Pa), a Pt-rich layer (0 to 2.6 nm, 4 Pa), and a C surface protective layer (7 nm, 0.6 Pa) stacked in this order. Here, the figures within the parentheses represent the thickness (nm) and the Ar atmosphere pressure (Pa) during sputtering. The Ru underlayer 2 is a layer stacked for forming a surface concavo-convex shape. The Pt-rich layer and the Co-rich magnetic layer were deposited at room temperature without elevating the temperature of the substrate.

[Preparation of Magnetic Recording Medium Samples C]

Each magnetic recording medium sample C was prepared, through sputtering with a DC sputtering apparatus using the prepared sputtering target, by stacking, on a Ru underlayer, a Co-rich magnetic layer of CoPt-base alloy-oxide having the composition shown in each Example or Comparative Example below at the thickness shown in each Example or Comparative Example, stacking, on the resulting Co-rich magnetic layer, a Pt-base alloy-oxide thin layer (Pt-rich buffer layer) having the composition shown in each Example or Comparative Example at the thickness shown in each Example or Comparative Example, and subsequently repeating stacking of a Co-rich magnetic layer and a Pt-rich buffer layer in the above-mentioned order three times.

As shown in FIG. 3-C, each magnetic recording medium sample C comprises, on a glass substrate, a Ta layer (5 nm, 0.6 Pa), a Ni90W10 seed layer (6 nm, 0.6 Pa), a Ru underlayer 1 (10 nm, 0.6 Pa), a Ru underlayer 2 (10 nm, 8.0 Pa), a Co-rich magnetic layer 1 (4 nm, 4 Pa), a Pt-rich layer 1 (0 to 0.8 nm, 4 Pa), a Co-rich magnetic layer 2 (4 nm, 4 Pa), a Pt-rich layer 2 (0 to 0.8 nm, 4 Pa), a Co-rich magnetic layer 3 (4 nm, 4 Pa), a Pt-rich layer 3 (0 to 0.8 nm, 4 Pa), a Co-rich magnetic layer 4 (4 nm, 4 Pa), a Pt-rich layer 4 (0 to 0.8 nm, 4 Pa), and a C surface protective layer (7 nm, 0.6 Pa) stacked in this order. Here, the figures within the parentheses represent the thickness (nm) and the Ar atmosphere pressure (Pa) during sputtering. The Ru underlayer 2 is a layer stacked for forming a surface concavo-convex shape. The Pt-rich layers and the Co-rich magnetic layers were deposited at room temperature without elevating the temperature of the substrate.

As for the magnetic characteristics of each magnetic recording medium sample, the coercivity H_{c} was measured using a vibrating sample magnetometer (VSM: TM-VSM211483-HGC from Tamagawa Co., Ltd.), and the magnetocrystalline anisotropy constant Kᵤ was measured using a torque magnetometer (TM-TR2050-HGC from Tamagawa Co., Ltd.).

[Magnetic Characteristics and Thickness of Pt-rich Buffer Layer (1)]

The magnetic characteristics were investigated in Comparative Examples 1 and 2 as well as Examples 1 to 9 by changing the thickness of the Pt-rich buffer layer from 0 nm to 2.5 nm.

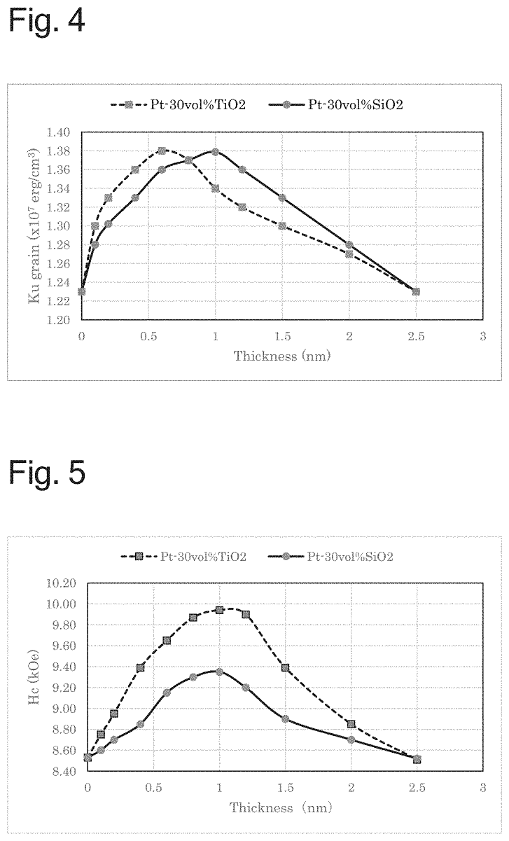

Here, the Pt-rich buffer layer was Pt-30 vol % TiO₂, and the Co-rich magnetic layer was Co80Pt20-30 vol % B₂O₃ of 16 nm in thickness. The results are shown in Table 1 and FIGS. 4 and 5. In the table and the figures, K_{u grain} represents the magnetocrystalline anisotropy constant (Kᵤ) for the respective magnetic grains.

[Table 1]

TABLE 1
Magnetic Characteristics and Thickness
of Pt-rich Layer (Pt-30 vol % TiO₂)

| | Thickness of | Thickness of | | |
|---|---|---|---|---|
| | Pt-rich | Co-rich | | |
| | buffer layer | magnetic layer | K_{u grain} | H_{c} |
| | (nm) | (nm) | (×10⁷ erg/cm³) | (kOe) |
| Comp. Ex. 1 | 0 | 16 | 1.23 | 8.53 |
| Ex. 1 | 0.1 | 16 | 1.30 | 8.75 |
| Ex. 2 | 0.2 | 16 | 1.33 | 8.95 |
| Ex. 3 | 0.4 | 16 | 1.36 | 9.39 |
| Ex. 4 | 0.6 | 16 | 1.38 | 9.65 |
| Ex. 5 | 0.8 | 16 | 1.37 | 9.87 |
| Ex. 6 | 1.0 | 16 | 1.34 | 9.94 |
| Ex. 7 | 1.2 | 16 | 1.32 | 9.90 |
| Ex. 8 | 1.5 | 16 | 1.30 | 9.39 |
| Ex. 9 | 2.0 | 16 | 1.27 | 8.85 |
| Comp. Ex. 2 | 2.5 | 16 | 1.23 | 8.51 |

It was confirmed that both magnetocrystalline anisotropy constant K_{u grain} and coercivity H_{c} increase relative to those of Comparative Example 1, in which no Pt-rich buffer layer is provided, when the thickness of the Pt-rich buffer layer is 0.1 nm or more and 2.0 nm or less and become comparable to those of Comparative Example 1 when the thickness reaches 2.5 nm. Meanwhile, it is found that the magnetocrystalline anisotropy constant K_{u grain} reaches the largest of 1.38×10⁷ erg/cm³ when the thickness is 0.6 nm and remains large as 1.30×10⁷ erg/cm³ or more when the thickness falls within the range of 0.1 nm or more and 1.5 nm or less. Moreover, it is found that the coercivity H_{c} reaches the highest of 9.94 kOe when the thickness is 1.0 nm and remains high as 9.39 kOe or more when the thickness falls within the range of 0.4 nm or more and 1.5 nm or less.

[Magnetic Characteristics and Thickness of Pt-rich Buffer Layer (2)]

The magnetic characteristics were investigated in Comparative Examples 1 and 3 as well as Examples 10 to 18 by changing the thickness of the Pt-rich buffer layer from 0 nm to 2.5 nm.

Here, the Pt-rich buffer layer was Pt-30 vol % SiO₂, and the Co-rich magnetic layer was Co80Pt20-30 vol % B₂O₃ of 16 nm in thickness. The results are shown in Table 2 and FIGS. 4 and 5.

TABLE 2
Magnetic Characteristics and Thickness of
Pt-rich Buffer Layer (Pt-30 vol % SiO₂)

| | Thickness of | Thickness of | | |
|---|---|---|---|---|
| | Pt-rich | Co-rich | | |
| | buffer layer | magnetic layer | K_{u grain} | H_{c} |
| | (nm) | (nm) | (×10⁷ erg/cm³) | (kOe) |
| Comp. Ex. 1 | 0 | 16 | 1.23 | 8.53 |
| Ex. 10 | 0.1 | 16 | 1.28 | 8.60 |
| Ex. 11 | 0.2 | 16 | 1.30 | 8.70 |
| Ex. 12 | 0.4 | 16 | 1.33 | 8.85 |
| Ex. 13 | 0.6 | 16 | 1.36 | 9.15 |
| Ex. 14 | 0.8 | 16 | 1.37 | 9.30 |
| Ex. 15 | 1.0 | 16 | 1.38 | 9.35 |
| Ex. 16 | 1.2 | 16 | 1.36 | 9.20 |
| Ex. 17 | 1.5 | 16 | 1.33 | 8.90 |
| Ex. 18 | 2.0 | 16 | 1.28 | 8.70 |
| Comp. Ex. 3 | 2.5 | 16 | 1.23 | 8.52 |

It was confirmed that both magnetocrystalline anisotropy constant K_{u grain} and coercivity H_{c} increase relative to those of Comparative Example 1, in which no Pt-rich buffer layer is provided, when the thickness of the Pt-rich buffer layer is 0.1 nm or more and 2.0 nm or less and become comparable to those of Comparative Example 1 when the thickness reaches 2.5 nm. Meanwhile, it is found that the magnetocrystalline anisotropy constant K_{u grain} reaches the largest of 1.38×10⁷ erg/cm³ when the thickness is 1.0 nm and remains large as 1.30×10⁷ erg/cm³ or more when the thickness falls within the range of 0.2 nm or more and less than 2.0 nm. Moreover, it is found that the coercivity H_{c} reaches the highest of 9.35 kOe when the thickness is 1.0 nm and remains high as 8.90 kOe or more when the thickness falls within the range of more than 0.4 nm and 1.5 nm or less.

Further, as shown in FIGS. 4 and 5, it is revealed that both magnetocrystalline anisotropy constant K_{u grain} and coercivity H_{c} increase compared with those of Comparative Example 1 regardless of the types of oxides when the thickness of the Pt-rich buffer layer falls within the range of more than 0 nm and 2 nm or less.

[Magnetic Characteristics and Oxide (TiO₂) Content in Pt-rich Buffer Layer]

The magnetic characteristics were investigated in Comparative Examples 4 to 6 and Examples 19 to 25 by changing the oxide (TiO₂) content in the Pt-rich layer from 0 vol % to 45 vol %.

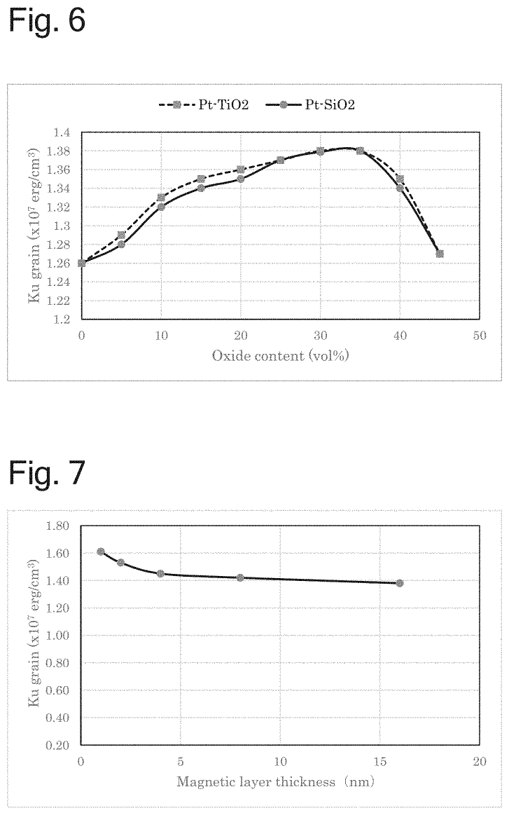

Here, the Pt-rich buffer layer was Pt—TiO₂ of 1.0 nm in thickness, and the Co-rich magnetic layer was Co80Pt20-30 vol % B₂O₃ of 16 nm in thickness. The results are shown in Table 3 and FIG. 6.

TABLE 3
Magnetic Characteristics and Oxide
Content in Pt-rich Buffer Layer

| | Composition of | K_{u grain} | H_{c} |
|---|---|---|---|
| | Pt-rich buffer layer | (×10⁷ erg/cm³) | (kOe) |
| Comp. Ex. 4 | Pt | 1.26 | 7.70 |
| Comp. Ex. 5 | Pt-5 vol % TiO₂ | 1.29 | 8.52 |
| Ex. 19 | Pt-10 vol % TiO₂ | 1.33 | 8.85 |
| Ex. 20 | Pt-15 vol % TiO₂ | 1.35 | 8.95 |
| Ex. 21 | Pt-20 vol % TiO₂ | 1.36 | 9.23 |
| Ex. 22 | Pt-25 vol % TiO₂ | 1.37 | 9.45 |
| Ex. 23 | Pt-30 vol % TiO₂ | 1.38 | 9.94 |
| Ex. 24 | Pt-35 vol % TiO₂ | 1.38 | 10.1 |
| Ex. 25 | Pt-40 vol % TiO₂ | 1.35 | 9.85 |
| Comp. Ex. 6 | Pt-45 vol % TiO₂ | 1.27 | 7.95 |

It was confirmed that both magnetocrystalline anisotropy constant K_{u grain} and coercivity H_{c} increase relative to those of Comparative Example 4, in which the Pt-rich buffer layer contains no oxide, when the oxide content in the Pt-rich buffer layer is 10 vol % or more and 40 vol % or less and become comparable to those of Comparative Example 1 when the oxide content reaches 45 vol %. Meanwhile, it is found that the magnetocrystalline anisotropy constant K_{u grain} remains extremely large as 1.35×10⁷ erg/cm³ or more and 1.38×10⁷ erg/cm³ or less when the oxide content falls within the range of 15 vol % or more and 40 vol % or less. Moreover, it is found that the coercivity H_{c} reaches the highest of 10.1 kOe when the oxide content is 35 vol % and remains high as 8.95 kOe or more when the oxide content falls within the range of 15 vol % or more and 40 vol % or less.

Further, as shown in FIG. 6, it is revealed that both magnetocrystalline anisotropy constant K_{u grain} and coercivity H_{c} increase regardless of the types of oxides when the oxide content is 10 vol % or more and 40 vol % or less.

[Magnetic Characteristics and Oxide (SiO₂) Content in Pt-rich Buffer Layer]

The magnetic characteristics were investigated in Comparative Examples 4, 7, and 8 as well as Examples 26 to 32 by changing the oxide (SiO₂) content in the Pt-rich buffer layer from 0 vol % to 45 vol %.

Here, the Pt-rich buffer layer was Pt—SiO₂ of 1.0 nm in thickness, and the Co-rich magnetic layer was Co80Pt20-30 vol % B₂O₃ of 16 nm in thickness. The results are shown in Table 4 and FIG. 6.

TABLE 4
Magnetic Characteristics and Oxide
Content in Pt-rich Buffer Layer

| | Composition of | K_{u grain} | H_{c} |
|---|---|---|---|
| | Pt-rich buffer layer | (×10⁷ erg/cm³) | (kOe) |
| Comp. Ex. 4 | Pt | 1.26 | 7.70 |
| Comp. Ex. 7 | Pt-5 vol % SiO₂ | 1.28 | 8.49 |
| Ex. 26 | Pt-10 vol % SiO₂ | 1.32 | 8.75 |
| Ex. 27 | Pt-15 vol % SiO₂ | 1.34 | 8.95 |
| Ex. 28 | Pt-20 vol % SiO₂ | 1.35 | 9.10 |
| Ex. 29 | Pt-25 vol % SiO₂ | 1.37 | 9.25 |
| Ex. 30 | Pt-30 vol % SiO₂ | 1.38 | 9.35 |
| Ex. 31 | Pt-35 vol % SiO₂ | 1.38 | 9.55 |
| Ex. 32 | Pt-40 vol % SiO₂ | 1.34 | 9.25 |
| Comp. Ex. 8 | Pt-45 vol % SiO₂ | 1.27 | 7.85 |

It was confirmed that both magnetocrystalline anisotropy constant K_{u grain} and coercivity H_{c} increase relative to those of Comparative Example 4, in which the Pt-rich buffer layer contains no oxide, when the oxide content in the Pt-rich buffer layer is 10 vol % or more and 40 vol % or less and become comparable to those of Comparative Example 1 when the oxide content reaches 45 vol %. Meanwhile, it is found that the magnetocrystalline anisotropy constant K_{u grain} remains extremely large as 1.34×10⁷ erg/cm³ or more and 1.38×10⁷ erg/cm³ or less when the oxide content falls within the range of 15 vol % or more and 40 vol % or less. Moreover, it is found that the coercivity H_{c} reaches the highest of 9.55 kOe when the oxide content is 35 vol % and remains high as 8.95 kOe or more when the oxide content falls within the range of 15 vol % or more and 40 vol % or less.

[Magnetic Characteristics and Types of Oxides in Pt-rich Buffer Layer]

The magnetic characteristics were investigated in Comparative Example 1 and Examples 33 to 43 by changing oxides in the Pt-rich buffer layer.

Here, the Pt-rich buffer layer had a thickness of 1.0 nm, and the Co-rich magnetic layer was Co80Pt20-30 vol % B₂O₃ of 16 nm in thickness. The results are shown in Table 5.

TABLE 5
Magnetic Characteristics and Types
of Oxides in Pt-rich Buffer Layer

| | Composition of | K_{u grain} | H_{c} |
|---|---|---|---|
| | Pt-rich buffer layer | (×10⁷ erg/cm³) | (kOe) |
| Comp. Ex. 1 | — | 1.23 | 8.53 |
| Ex. 33 | Pt-30 vol % B₂O₃ | 1.33 | 8.95 |
| Ex. 34 | Pt-30 vol % WO₃ | 1.35 | 9.15 |
| Ex. 35 | Pt-30 vol % Nb₂O₅ | 1.36 | 9.20 |
| Ex. 36 | Pt-30 vol % SiO₂ | 1.38 | 9.35 |
| Ex. 37 | Pt-30 vol % Ta₂O₅ | 1.39 | 9.63 |
| Ex. 38 | Pt-30 vol % TiO₂ | 1.38 | 9.94 |
| Ex. 39 | Pt-30 vol % Al₂O₃ | 1.39 | 10.12 |
| Ex. 40 | Pt-30 vol % Y₂O₃ | 1.41 | 10.21 |
| Ex. 41 | Pt-30 vol % CrO₃ | 1.41 | 10.12 |
| Ex. 42 | Pt-30 vol % ZrO₂ | 1.42 | 10.07 |
| Ex. 43 | Pt-30 vol % HfO₂ | 1.39 | 9.98 |
| Ex. 44 | Pt-15 vol % TiO₂-15 vol % B₂O₃ | 1.37 | 9.62 |
| Ex. 45 | Pt-15 vol % TiO₂-15 vol % WO₃ | 1.36 | 9.71 |
| Ex. 46 | Pt-15 vol % TiO₂-15 vol % Nb₂O₅ | 1.35 | 9.52 |
| Ex. 47 | Pt-15 vol % TiO₂-15 vol % SiO₂ | 1.37 | 9.97 |
| Ex. 48 | Pt-15 vol % TiO₂-15 vol % Ta₂O₅ | 1.36 | 9.98 |
| Ex. 49 | Pt-15 vol % TiO₂-15 vol % Al₂O₃ | 1.35 | 9.77 |
| Ex. 50 | Pt-15 vol % TiO₂-15 vol % Y₂O₃ | 1.35 | 9.98 |
| Ex. 51 | Pt-15 vol % TiO₂-15 vol % Cr₂O₃ | 1.35 | 9.67 |
| Ex. 52 | Pt-15 vol % TiO₂-15 vol % ZrO₂ | 1.36 | 9.98 |
| Ex. 53 | Pt-15 vol % TiO₂-15 vol % HfO₂ | 1.35 | 9.98 |

Relative to Comparative Example 1, in which no Pt-rich buffer layer is provided, it was confirmed that Examples 33 to 53, in which a Pt-rich buffer layer is provided, exhibit both a large magnetocrystalline anisotropy constant K_{u grain} and a high coercivity H_{c} regardless of the types of oxides or even when a plurality of oxides are contained.

[Magnetic Characteristics and Types of Additional Elements in Pt-rich Buffer Layer]

The magnetic characteristics were investigated in Comparative Example 1 and Examples 54 to 66 by changing additional elements in the Pt-base alloy of the Pt-rich buffer layer.

Here, the Pt-rich buffer layer was Pt95M5-30 vol % TiO₂ (M represents an additional element) of 1.0 nm in thickness, and the Co-rich magnetic layer was Co80Pt20-30 vol % B₂O₃ of 16 nm in thickness. The results are shown in Table 6.

TABLE 6
Magnetic Characteristics and Types of Additional
Elements in Pt-rich Buffer Layer

| | Composition of | K_{u grain} | H_{c} |
|---|---|---|---|
| | Pt-rich buffer layer | (×10⁷ erg/cm³) | (kOe) |
| Comp. Ex. 1 | — | 1.23 | 8.53 |
| Ex. 54 | Pt95Si5-30 vol % TiO₂ | 1.35 | 9.35 |
| Ex. 55 | Pt95Ti5-30 vol % TiO₂ | 1.37 | 9.75 |
| Ex. 56 | Pt95Cr5-30 vol % TiO₂ | 1.34 | 9.45 |
| Ex. 57 | Pt95B5-30 vol % TiO₂ | 1.38 | 10.32 |
| Ex. 58 | Pt95V5-30 vol % TiO₂ | 1.38 | 10.14 |
| Ex. 59 | Pt95Nb5-30 vol % TiO₂ | 1.37 | 9.89 |
| Ex. 60 | Pt95Ta5-30 vol % TiO₂ | 1.36 | 10.13 |
| Ex. 61 | Pt95Ru5-30 vol % TiO₂ | 1.39 | 9.85 |
| Ex. 62 | Pt95Mn5-30 vol % TiO₂ | 1.37 | 10.04 |
| Ex. 63 | Pt95Zn5-30 vol % TiO₂ | 1.37 | 9.98 |
| Ex. 64 | Pt95Mo5-30 vol % TiO₂ | 1.39 | 10.01 |
| Ex. 65 | Pt95W5-30 vol % TiO₂ | 1.39 | 10.05 |
| Ex. 66 | Pt95Ge5-30 vol % TiO₂ | 1.36 | 10.08 |

Relative to Comparative Example 1, in which no Pt-rich buffer layer is provided, it was confirmed that Examples 54 to 66, in which a Pt-rich buffer layer is provided, exhibit both a large magnetocrystalline anisotropy constant K_{u grain} and a high coercivity H_{c} regardless of the types of additional elements.

[Magnetic Characteristics and Pt Content in Pt-rich Buffer Layer]

The magnetic characteristics were investigated in Comparative Examples 1 and 9 as well as Examples 67 to 73 by changing the Pt content in the Pt-rich buffer layer.

Here, the Pt-rich buffer layer was PtTi-30 vol % TiO₂ of 1.0 nm in thickness, and the Co-rich magnetic layer was Co80Pt20-30 vol % B₂O₃ of 16 nm in thickness. The results are shown in Table 7.

TABLE 7
Magnetic Characteristics and Pt Content in Pt-rich Buffer Layer

| | Composition of | K_{u grain} | H_{c} |
|---|---|---|---|
| | Pt-rich buffer layer | (×10⁷ erg/cm³) | (kOe) |
| Comp. Ex. 1 | — | 1.23 | 8.53 |
| Ex. 67 | Pt-30 vol % TiO₂ | 1.38 | 9.94 |
| Ex. 68 | Pt95Ti5-30 vol % TiO₂ | 1.37 | 9.75 |
| Ex. 69 | Pt80Til0-30 vol % TiO₂ | 1.35 | 9.63 |
| Ex. 70 | Pt80Ti20-30 vol % TiO₂ | 1.32 | 9.52 |
| Ex. 71 | Pt70Ti30-30 vol % TiO₂ | 1.28 | 9.34 |
| Ex. 72 | Pt60Ti40-30 vol % TiO₂ | 1.26 | 9.03 |
| Ex. 73 | Pt50Ti50-30 vol % TiO₂ | 1.24 | 8.75 |
| Comp. Ex. 9 | Pt45Ti55-30 vol % TiO₂ | 1.19 | 8.23 |

It was confirmed that the magnetocrystalline anisotropy constant K_{u grain} and the coercivity H_{c} increase relative to those of Comparative Example 1, in which no Pt-rich buffer layer is provided, as the Pt content in the Pt-rich buffer layer increases and decrease to be comparable to those of Comparative Example 1 when the Pt content is 45 at % in Comparative Example 9.

[Magnetic Characteristics and Thickness of Co-rich Magnetic Layer]

The magnetic characteristics and the thickness of the Co-rich magnetic layer were investigated in Examples 74 to 78.

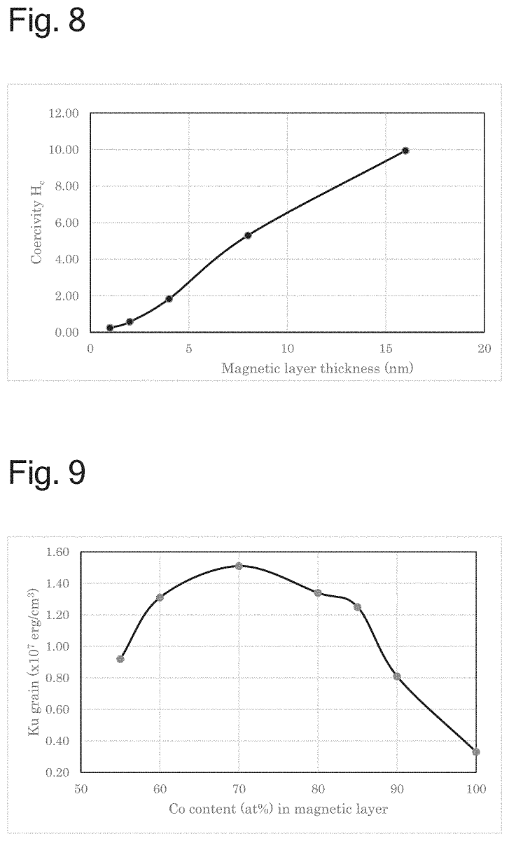

Here, the Pt-rich buffer layer was Pt-30 vol % TiO₂ of 1.0 nm in thickness, and the Co-rich magnetic layer was Co80Pt20-30 vol % B₂O₃. The results are shown in Table 8 and FIGS. 7 and 8.

TABLE 8
Magnetic Characteristics and Thickness of Co-rich Magnetic Layer

| | Thickness of | | |
|---|---|---|---|
| | Co-rich magnetic layer | K_{u grain} | H_{c} |
| | (nm) | (×10⁷ erg/cm³) | (kOe) |
| Ex. 74 | 1 | 1.61 | 0.24 |
| Ex. 75 | 2 | 1.53 | 0.57 |
| Ex. 76 | 4 | 1.45 | 1.83 |
| Ex. 77 | 8 | 1.42 | 5.30 |
| Ex. 78 | 16 | 1.38 | 9.94 |

It was confirmed that the magnetocrystalline anisotropy constant K_{u grain} slightly decreases but the coercivity H_{c} increases as the thickness of the Co-rich magnetic layer increases.

[Magnetic Characteristics and Oxide Content in Co-rich Magnetic Layer]

The magnetic characteristics and the oxide content in the Co-rich magnetic layer were investigated in Comparative Examples 10 and 11 as well as Examples 79 to 82.

Here, the Pt-rich buffer layer was Pt-30 vol % TiO₂ of 1.0 nm in thickness, and the Co-rich magnetic layer was Co80Pt20-B₂O₃ of 16 nm in thickness. The results are shown in Table 9.

TABLE 9
Magnetic Characteristics and Oxide
Content in Co-rich Magnetic Layer

| | Composition of | K_{u grain} | H_{c} |
|---|---|---|---|
| | Co-rich magnetic layer | (×10⁷ erg/cm³) | (kOe) |
| Comp. Ex. 10 | Co80Pt20 | 1.29 | 0.30 |
| Ex. 79 | Co80Pt20-10 vol % B₂O₃ | 1.47 | 5.41 |
| Ex. 80 | Co80Pt20-20 vol % B₂O₃ | 1.43 | 8.54 |
| Ex. 81 | Co80Pt20-30 vol % B₂O₃ | 1.38 | 9.94 |
| Ex. 82 | Co80Pt20-40 vol % B₂O₃ | 1.36 | 10.37 |
| Comp. Ex. 11 | Co80Pt20-45 vol % B₂O₃ | 1.31 | 9.37 |

It was confirmed that the magnetocrystalline anisotropy constant K_{u grain} decreases but the coercivity H_{c} increases as the oxide content in the Co-rich magnetic layer increases within the range of 10 vol % or more and 40 vol % or less. When the oxide content is 45 vol %, the coercivity H_{c} is high but the magnetocrystalline anisotropy constant K_{u grain} is comparable to that of Comparative Example 10, in which no oxide is contained.

[Magnetic Characteristics and Types of Oxides in Co-rich Magnetic Layer]

The magnetic characteristics and the types of oxides in the Co-rich magnetic layer were investigated in Examples 83 to 99.

Here, the Pt-rich buffer layer was Pt-30 vol % TiO₂ of 1.0 nm in thickness, and the Co-rich magnetic layer was Co80Pt20-30 vol % XO (XO represents an oxide) of 16 nm in thickness. The results are shown in Table 10.

TABLE 10
Magnetic Characteristics and Types of Oxides in Co-rich Magnetic Layer

| | Composition of | K_{u grain} | H_{c} |
|---|---|---|---|
| | Co-rich magnetic layer | (×10⁷ erg/cm³) | (kOe) |
| Ex. 83 | Co80Pt20-30 vol % B₂O₃ | 1.38 | 9.94 |
| Ex. 84 | Co80Pt20-30 vol % WO₃ | 1.35 | 8.85 |
| Ex. 85 | Co80Pt20-30 vol % Nb₂O₅ | 1.30 | 8.75 |
| Ex. 86 | Co80Pt20-30 vol % SiO₂ | 1.31 | 8.61 |
| Ex. 87 | Co80Pt20-30 vol % Ta₂O₅ | 1.32 | 8.61 |
| Ex. 88 | Co80Pt20-30 vol % TiO₂ | 1.34 | 8.71 |
| Ex. 89 | Co80Pt20-15 vol % B₂O₃-15 vol % TiO₂ | 1.37 | 10.14 |
| Ex. 90 | Co80Pt20-15 vol % B₂O₃-15 vol % SiO₂ | 1.35 | 10.15 |
| Ex. 91 | Co80Pt20-15 vol % B₂O₃-15 vol % Cr₂O₃ | 1.39 | 9.75 |
| Ex. 92 | Co80Pt20-15 vol % B₂O₃-15 vol % WO₃ | 1.35 | 9.96 |
| Ex. 93 | Co80Pt20-15 vol % B₂O₃-15 vol % Nb₂O₅ | 1.37 | 9.81 |
| Ex. 94 | Co80Pt20-15 vol % B₂O₃-15 vol % Ta₂O₅ | 1.36 | 10.17 |
| Ex. 95 | Co80Pt20-10 vol % B₂O₃-10 vol % TiO₂-10 vol % SiO₂ | 1.38 | 9.94 |
| Ex. 96 | Co80Pt20-10 vol % B₂O₃-10 vol % SiO₂-10 vol % Cr₂O₃ | 1.39 | 9.85 |
| Ex. 97 | Co80Pt20-10 vol % B₂O₃-10 vol % TiO₂-10 vol % Cr₂O₃ | 1.39 | 9.75 |
| Ex. 98 | Co80Pt20-10 vol % B₂O₃-10 vol % SiO₂-10 vol % CoO | 1.38 | 9.61 |
| Ex. 99 | Co80Pt20-10 vol % B₂O₃-10 vol % TiO₂-10 vol % CoO | 1.39 | 9.63 |

A large magnetocrystalline anisotropy constant K_{u grain} and a high coercivity H_{c} were confirmed regardless of the types of oxides in the Co-rich magnetic layer or even when a plurality of oxides are contained.

[Magnetic Characteristics and Co Content in Co-rich Magnetic Layer]

The magnetic characteristics and the Co content in the Co-rich magnetic layer were investigated in Comparative Examples 12 to 14 and Examples 100 to 103.

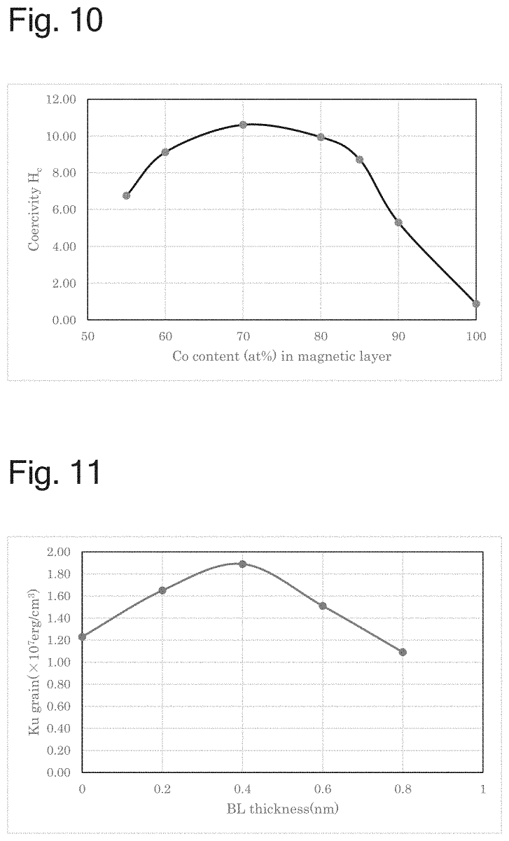

Here, the Pt-rich buffer layer was Pt-30 vol % TiO₂ of 1.0 nm in thickness, and the Co-rich magnetic layer was CoPt-30 vol % B₂O₃ of 16 nm in thickness. The results are shown in Table 11 and FIGS. 9 and 10.

TABLE 11
Magnetic Characteristics and Co
Content in Co-rich Magnetic Layer

| | Composition of | K_{u grain} | H_{c} |
|---|---|---|---|
| | Co-rich magnetic layer | (×10⁷ erg/cm³) | (kOe) |
| Comp. Ex. 12 | Co-30 vol % B₂O₃ | 0.33 | 0.87 |
| Comp. Ex. 13 | Co90Pt10-30 vol % B₂O₃ | 0.81 | 5.30 |
| Ex. 100 | Co85Pt15-30 vol % B₂O₃ | 1.25 | 8.72 |
| Ex. 101 | Co80Pt20-30 vol % B₂O₃ | 1.34 | 9.94 |
| Ex. 102 | Co70Pt30-30 vol % B₂O₃ | 1.51 | 10.61 |
| Ex. 103 | Co60Pt40-30 vol % B₂O₃ | 1.31 | 9.12 |
| Comp. Ex. 14 | Co55Pt45-30 vol % B₂O₃ | 0.92 | 6.76 |

It was confirmed that the magnetocrystalline anisotropy constant K_{u grain} remains large as 1.25×10⁷ erg/cm³ or more and the coercivity H_{c} remains high as 8.72 kOe or more when the Co content in the Co-rich magnetic layer falls within the range of 60 at % or more and 85 at % or less.

[Magnetic Characteristics and Types of Additional Elements in Co-rich Magnetic Layer]

The magnetic characteristics and the types of additional elements in the Co-rich magnetic layer were investigated in Examples 104 to 107.

Here, the Pt-rich layer was Pt-30 vol % TiO₂ of 1.0 nm in thickness, and the Co-rich magnetic layer was CoPtM-30 vol % B₂O₃ (M represents an additional element) of 16 nm in thickness. The results are shown in Table 12.

TABLE 12
Magnetic Characteristics and Types of Additional
Elements in Co-rich Magnetic Layer

| | Composition of | K_{u grain} | H_{c} |
|---|---|---|---|
| | Co-rich magnetic layer | (×10⁷ erg/cm³) | (kOe) |
| Ex. 104 | Co75Pt20Cr5-30 vol % B₂O₃ | 1.31 | 10.15 |
| Ex. 105 | Co75Pt20B5-30 vol % B₂O₃ | 1.38 | 10.25 |
| Ex. 106 | Co75Pt20Ru5-30 vol % B₂O₃ | 1.36 | 9.59 |
| Ex. 107 | Co75Pt20Ti5-30 vol % B₂O₃ | 1.33 | 10.05 |

A large magnetocrystalline anisotropy constant K_{u grain} and a high coercivity H_{c} were confirmed regardless of the types of additional elements in the Co-rich magnetic layer.

[Magnetic Characteristics and Stacked Position of Pt-rich Buffer Layer]

The magnetic characteristics and the stacked position of the Pt-rich buffer layer were investigated in Comparative Example 1 and Examples 108 and 109.

Here, the Pt-rich buffer layer was Pt-30 vol % TiO₂ of 1.0 nm in thickness, and the Co-rich magnetic layer was CoPt-30 vol % B₂O₃ of 16 nm in thickness. The results are shown in Table 13.

TABLE 13
Magnetic Characteristics and Stacked
Position of Pt-rich Buffer Layer

| | Stacked position of | K_{u grain} | H_{c} |
|---|---|---|---|
| | Pt-rich buffer layer | (×10⁷ erg/cm³) | (kOe) |
| Comp. Ex. 1 | — | 1.23 | 8.53 |
| Ex. 108 | under Co-rich magnetic layer | 1.38 | 9.94 |
| Ex. 109 | on Co-rich magnetic layer | 1.38 | 8.95 |

It was confirmed that both magnetocrystalline anisotropy constant K_{u grain} and coercivity H_{c} increase compared with those of Comparative Example 1, in which no Pt-rich buffer layer is stacked, in either case of stacking the Pt-rich buffer layer under or on the Co-rich magnetic layer; the magnetocrystalline anisotropy constant K_{u grain} is the same value in either case; and the coercivity H_{c} is higher in the case of stacking under the Co-rich magnetic layer.

[Stacked Position and Thickness of Pt-rich Buffer Layer and Magnetic Characteristics]

The stacked position and thickness of the Pt-rich buffer layer and the magnetic characteristics were investigated in Comparative Examples 15 and 16 as well as Examples 110 to 122.

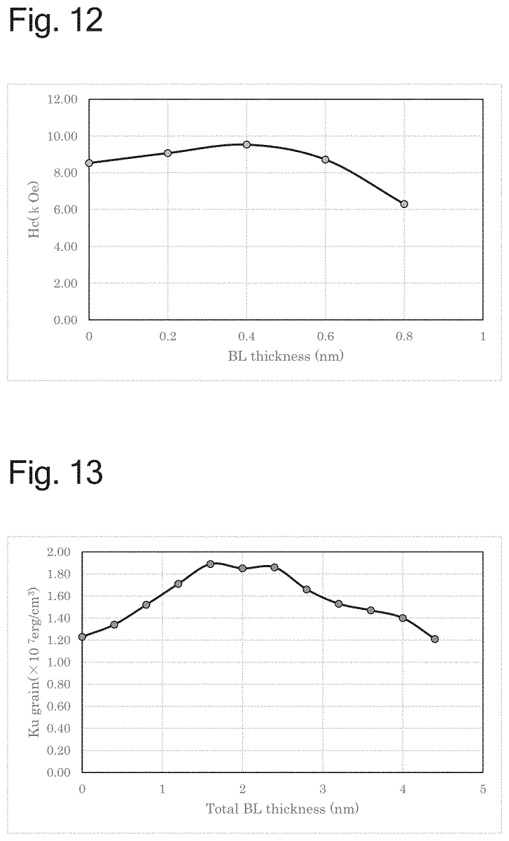

Here, the Pt-rich buffer layer was Pt-30 vol % SiO₂, and the Co-rich magnetic layer was Co80Pt20-30 vol % B₂O₃. The thickness of the Co-rich magnetic layer was set to 16 nm in Examples 110 to 119, and the thickness of the Co-rich magnetic layers was set to 4 nm for each layer and 16 nm in total in Examples 120 to 122 and Comparative Examples 15 and 16. The results are shown in Table 14. Moreover, the relationship between the thickness of the Pt-rich buffer layer and K_{u grain} and the relationship between the thickness of the Pt-rich buffer layer and H_{c} in Examples 120 to 122 and Comparative Example 16, in which the Pt-rich buffer layers are stacked between the Co-rich magnetic layers, are shown respectively in FIGS. 11 and 12.

TABLE 14
Stacked Position and Thickness of Pt-rich
Buffer Layer and Magnetic Characteristics

| | Pt-rich buffer layer | | | |
|---|---|---|---|---|
| | | Thickness | K_{u grain} | H_{c} |
| | Stacked position | (nm) | (×10⁷ erg/cm³) | (kOe) |
| Comp. Ex. 15 | — | 0 | 1.23 | 8.53 |
| Ex. 110 | on Co-rich magnetic layer | 0.2 | 1.33 | 9.46 |
| Ex. 111 | on Co-rich magnetic layer | 0.4 | 1.34 | 9.66 |
| Ex. 112 | on Co-rich magnetic layer | 0.5 | 1.36 | 9.61 |
| Ex. 113 | on Co-rich magnetic layer | 0.7 | 1.35 | 9.63 |
| Ex. 114 | on Co-rich magnetic layer | 0.9 | 1.35 | 9.76 |
| Ex. 115 | on Co-rich magnetic layer | 1.1 | 1.37 | 9.71 |
| Ex. 116 | on Co-rich magnetic layer | 1.3 | 1.37 | 9.72 |
| Ex. 117 | on Co-rich magnetic layer | 1.7 | 1.36 | 9.74 |
| Ex. 118 | on Co-rich magnetic layer | 2.2 | 1.35 | 9.76 |
| Ex. 119 | on Co-rich magnetic layer | 2.6 | 1.36 | 9.77 |
| Comp. Ex. 16 | between Co-rich magnetic layers | 0.8 | 1.09 | 6.30 |
| Ex. 120 | between Co-rich magnetic layers | 0.2 | 1.65 | 9.07 |
| Ex. 121 | between Co-rich magnetic layers | 0.4 | 1.89 | 9.53 |
| Ex. 122 | between Co-rich magnetic layers | 0.6 | 1.51 | 8.72 |

It was confirmed that both magnetocrystalline anisotropy constant K_{u grain} and coercivity H_{c} increase compared with those of Comparative Example 15, in which no Pt-rich buffer layer is stacked, in either case of stacking the Pt-rich buffer layer(s) on the Co-rich magnetic layer or between the Co-rich magnetic layers; and the magnetocrystalline anisotropy constant K_{u grain} is almost the same value in any example. Moreover, it was confirmed that the coercivity H_{c} increases as the thickness of the Pt-rich buffer layer increases and is higher at the same thickness in the case of stacking the Pt-rich buffer layer on the Co-rich magnetic layer than in the case of stacking between the Co-rich magnetic layers.

[Magnetic Characteristics and Each Thickness of Co-rich Magnetic Layers]

In Comparative Examples 15 and 17 as well as Examples 111, 121, and 123 to 130 in which the thickness of each Pt-rich buffer layer was set to 0.4 nm and the combination of a Pt-rich buffer layer stacked on a Co-rich magnetic layer was stacked a plurality of times, the magnetic characteristics were investigated by changing each thickness of the Co-rich magnetic layers and by changing the stacked number of a Co-rich magnetic layer and a Pt-rich buffer layer.

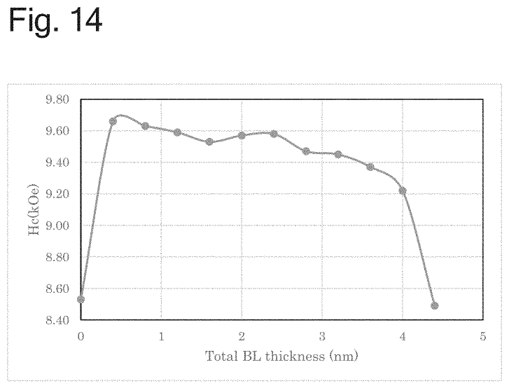

Here, the Pt-rich buffer layer was Pt-30 vol % SiO₂, and the Co-rich magnetic layer was Co80Pt20-30 vol % B₂O₃. The results are shown in Table 15. Moreover, the relationship between the total thickness of the Pt-rich layers and K_{u grain} and the relationship between the total thickness and H_{c} are shown respectively in FIGS. 13 and 14.

TABLE 15
Magnetic Characteristics and Thickness of Co-rich Magnetic
Layers/Pt-rich Buffer Layers Stacked Plurality of Times

| | | | | Total thickness | | |
|---|---|---|---|---|---|---|
| | Thickness | | | of buffer | | |
| | of each | | Thickness | layer(s) and | | |
| | magnetic | Stacked | of buffer | magnetic | K_{u grain} | H_{c} |
| | layer (nm) | number | layer (nm) | layer(s) (nm) | (×10⁷ erg/cm³) | (kOe) |
| Comp. Ex. 15 | 16 | 0 | 0 | 16.0 | 1.23 | 8.53 |
| Ex. 111 | 16 | 1 | 0.4 | 16.4 | 1.34 | 9.66 |
| Ex. 123 | 8 | 2 | 0.8 | 16.8 | 1.52 | 9.63 |
| Ex. 124 | 5.3 | 3 | 1.2 | 17.1 | 1.71 | 9.59 |
| Ex. 121 | 4 | 4 | 1.6 | 17.6 | 1.89 | 9.53 |
| Ex. 125 | 3.2 | 5 | 2.0 | 18.0 | 1.85 | 9.57 |
| Ex. 126 | 2.7 | 6 | 2.4 | 18.6 | 1.86 | 9.58 |
| Ex. 127 | 2.3 | 7 | 2.8 | 18.9 | 1.66 | 9.47 |
| Ex. 128 | 2 | 8 | 3.2 | 19.2 | 1.53 | 9.45 |
| Ex. 129 | 1.8 | 9 | 3.6 | 19.8 | 1.47 | 9.37 |
| Ex. 130 | 1.6 | 10 | 4.0 | 20.0 | 1.40 | 9.22 |
| Comp. Ex. 17 | 1.5 | 11 | 4.4 | 20.9 | 1.21 | 8.49 |

Compared with those of Comparative Example 15, in which no Pt-rich buffer layer is stacked, it was confirmed that both magnetocrystalline anisotropy constant K_{u grain} and coercivity increase by repeating stacking of a Co-rich magnetic layer and a Pt-rich buffer layer; whereas both magnetocrystalline anisotropy constant K_{u grain} and coercivity H_{c} decrease when the total thickness of Pt-rich buffer layers exceeds 4 nm and the total thickness of Co-rich magnetic layers and Pt-rich buffer layers exceeds 20 nm by repeating stacking of a Co-rich magnetic layer and a Pt-rich buffer layer 11 times.

1. A Pt-oxide-based sputtering target consisting of 60 vol % or more and less than 100 vol % of a Pt-base alloy phase and more than 0 vol % and 40 vol % or less of an oxide, wherein
the Pt-base alloy phase contains 50 at % or more and 100 at % or less of Pt.

2. The Pt-oxide-based sputtering target according to claim 1, wherein the Pt-base alloy phase further contains, in total, 0 at % or more and 50 at % or less of one or more selected from Si, Ti, Cr, B, V, Nb, Ta, Ru, Mn, Zn, Mo, W, and Ge.

3. The Pt-oxide-based sputtering target according to claim 1, wherein the oxide is one or more selected from B₂O₃, WO₃, Nb₂O₅, SiO₂, Ta₂O₅, TiO₂, Al₂O₃, Y₂O₃, Cr₂O₃, ZrO₂, and HfO₂.

4. A perpendicular magnetic recording medium comprising: a CoPt-base alloy-oxide granular magnetic layer containing Co-rich grains; and a Pt-base alloy-oxide thin layer containing Pt-rich grains and being stacked under the magnetic layer, wherein:
the granular magnetic layer consists of 60 vol % or more and less than 100 vol % of a CoPt-base alloy phase and more than 0 vol % and 40 vol % or less of an oxide;
the CoPt-base alloy phase of the magnetic layer contains 60 at % or more and 85 at % or less of Co and 15 at % or more and 40 at % or less of Pt;
the Pt-base alloy-oxide thin layer has a thickness of more than 0 nm and 2 nm or less and consists of 60 vol % or more and less than 100 vol % of a Pt-base alloy phase and more than 0 vol % and 40 vol % or less of an oxide; and
the Pt-base alloy phase of the Pt-base alloy-oxide thin layer contains 50 at % or more and 100 at % or less of Pt.

5. A perpendicular magnetic recording medium comprising: a CoPt-base alloy-oxide granular magnetic layer containing Co-rich grains; and a Pt-base alloy-oxide thin layer containing Pt-rich grains and being stacked on the magnetic layer, wherein:
the granular magnetic layer consists of 60 vol % or more and less than 100 vol % of a CoPt-base alloy phase and more than 0 vol % and 40 vol % or less of an oxide;
the CoPt-base alloy phase of the magnetic layer contains 60 at % or more and 85 at % or less of Co and 15 at % or more and 40 at % or less of Pt;
the Pt-base alloy-oxide thin layer has a thickness of more than 0 nm and 4 nm or less and consists of 60 vol % or more and less than 100 vol % of a Pt-base alloy phase and more than 0 vol % and 40 vol % or less of an oxide; and
the Pt-base alloy phase of the Pt-base alloy-oxide thin layer contains 50 at % or more and 100 at % or less of Pt.

6. A perpendicular magnetic recording medium comprising a plurality of combinations, each of which comprises: a CoPt-base alloy-oxide granular magnetic layer containing Co-rich grains; and a Pt-base alloy-oxide thin layer containing Pt-rich grains and being stacked on the magnetic layer, wherein:
the granular magnetic layer consists of 60 vol % or more and less than 100 vol % of a CoPt-base alloy phase and more than 0 vol % and 40 vol % or less of an oxide;
the CoPt-base alloy phase of the magnetic layer contains 60 at % or more and 85 at % or less of Co and 15 at % or more and 40 at % or less of Pt;
the Pt-base alloy-oxide thin layer consists of 60 vol % or more and less than 100 vol % of a Pt-base alloy phase and more than 0 vol % and 40 vol % or less of an oxide;
the Pt-base alloy phase of the Pt-base alloy-oxide thin layer contains 50 at % or more and 100 at % or less of Pt; and
a total thickness of the Pt-base alloy-oxide thin layers included in the perpendicular magnetic recording medium is more than 0 nm and 4 nm or less.

7. The perpendicular magnetic recording medium according to claim 4, wherein the Pt-base alloy phase of the Pt-base alloy-oxide thin layer further contains, in total, 0 at % or more and 50 at % or less of one or more selected from Si, Ti, Cr, B, V, Nb, Ta, Ru, Mn, Zn, Mo, W, and Ge.

8. The perpendicular magnetic recording medium according to claim 4, wherein the Pt-base alloy-oxide thin layer contains, in total, 0 vol % or more and 40 vol % or less of one or more oxides selected from B₂O₃, WO₃, Nb₂O₅, SiO₂, Ta₂O₅, TiO₂, Al₂O₃, Y₂O₃, Cr₂O₃, ZrO₂, and HfO₂.

9. The perpendicular magnetic recording medium according to claim 4, wherein the Pt-base alloy phase of the Pt-base alloy-oxide thin layer further contains, in total, 0 at % or more and 50 at % or less of one or more selected from Si, Ti, Cr, B, V, Nb, Ta, Ru, Mn, Zn, Mo, W, and Ge, and
wherein the Pt-base alloy-oxide thin layer contains, in total, 0 vol % or more and 40 vol % or less of one or more oxides selected from B₂O₃, WO₃, Nb₂O₅, SiO₂, Ta₂O₅, TiO₂, Al₂O₃, Y₂O₃, Cr₂O₃, ZrO₂, and HfO₂.

10. The perpendicular magnetic recording medium according to claim 5, wherein the Pt-base alloy phase of the Pt-base alloy-oxide thin layer further contains, in total, 0 at % or more and 50 at % or less of one or more selected from Si, Ti, Cr, B, V, Nb, Ta, Ru, Mn, Zn, Mo, W, and Ge.

11. The perpendicular magnetic recording medium according to claim 5, wherein the Pt-base alloy-oxide thin layer contains, in total, 0 vol % or more and 40 vol % or less of one or more oxides selected from B₂O₃, WO₃, Nb₂O₅, SiO₂, Ta₂O₅, TiO₂, Al₂O₃, Y₂O₃, Cr₂O₃, ZrO₂, and HfO₂.

12. The perpendicular magnetic recording medium according to claim 5, wherein the Pt-base alloy phase of the Pt-base alloy-oxide thin layer further contains, in total, 0 at % or more and 50 at % or less of one or more selected from Si, Ti, Cr, B, V, Nb, Ta, Ru, Mn, Zn, Mo, W, and Ge, and
wherein the Pt-base alloy-oxide thin layer contains, in total, 0 vol % or more and 40 vol % or less of one or more oxides selected from B₂O₃, WO₃, Nb₂O₅, SiO₂, Ta₂O₅, TiO₂, Al₂O₃, Y₂O₃, Cr₂O₃, ZrO₂, and HfO₂.

13. The perpendicular magnetic recording medium according to claim 6, wherein the Pt-base alloy phase of the Pt-base alloy-oxide thin layer further contains, in total, 0 at % or more and 50 at % or less of one or more selected from Si, Ti, Cr, B, V, Nb, Ta, Ru, Mn, Zn, Mo, W, and Ge.

14. The perpendicular magnetic recording medium according to claim 6, wherein the Pt-base alloy-oxide thin layer contains, in total, 0 vol % or more and 40 vol % or less of one or more oxides selected from B₂O₃, WO₃, Nb₂O₅, SiO₂, Ta₂O₅, TiO₂, Al₂O₃, Y₂O₃, Cr₂O₃, ZrO₂, and HfO₂.

15. The perpendicular magnetic recording medium according to claim 6, wherein the Pt-base alloy phase of the Pt-base alloy-oxide thin layer further contains, in total, 0 at % or more and 50 at % or less of one or more selected from Si, Ti, Cr, B, V, Nb, Ta, Ru, Mn, Zn, Mo, W, and Ge, and
wherein the Pt-base alloy-oxide thin layer contains, in total, 0 vol % or more and 40 vol % or less of one or more oxides selected from B₂O₃, WO₃, Nb₂O₅, SiO₂, Ta₂O₅, TiO₂, Al₂O₃, Y₂O₃, Cr₂O₃, ZrO₂, and HfO₂.

16. The Pt-oxide-based sputtering target according to claim 2, wherein the oxide is one or more selected from B₂O₃, WO₃, Nb₂O₅, SiO₂, Ta₂O₅, TiO₂, Al₂O₃, Y₂O₃, Cr₂O₃, ZrO₂, and HfO₂.
